(19) United States
(12) Patent Application Publication
(10) Pub. No.: US 2024/0103137 A1
(43) Pub. Date: Mar. 28, 2024

(54) ILLUMINATION SYSTEM

(71) Applicant: AMS SENSORS SINGAPORE PTE. LTD., Singapore (SG)

(72) Inventors: Harald ETSCHMAIER, Graz (AT); Ho Hoai Duc NGUYEN, Munich (DE); Jan Eite Bullema, Helmond (NL)

(21) Appl. No.: 18/256,216

(22) PCT Filed: Dec. 6, 2021
(86) PCT No.: PCT/SG2021/050750

§ 371 Date: Jun. 7, 2023

(30) Foreign Application Priority Data
Dec. 14, 2020 (GB) 2019694.5

(51) Int. Cl. G01S 7/481

(52) U.S. Cl. CPC G01S 7/4814; G01S 7/4817; H01S 5/183

(57) ABSTRACT

An illumination module may include an emitter configured to emit light along an optical axis of the illumination module and an optical system located on or over the emitter. The optical system may include a curved surface where the curved surface is tilted in a first direction, such that the optical system introduces optical aberration in the first direction.

### CROSS-REFERENCE TO RELATED APPLICATIONS

The present application is a national stage entry according to 35 U.S.C. § 371 of PCT application No.: PCT/SG2021/050750 filed on Dec. 6, 2021; which claims priority to British patent application 2019694.5, filed on Dec. 14, 2020; all of which are incorporated herein by reference in their entirety and for all purposes.

### TECHNICAL FIELD

The present disclosure relates to an illumination system for use, in particular though not exclusively, in a sensing system such as a 3D sensing system or a light detection and ranging (LIDAR) system. The present disclosure also relates to a method of manufacturing an illumination system and a method of operating an illumination system.

### BACKGROUND

It is known to perform LIDAR, for example for automotive applications, using a light source and a beam steering means such as a MEMS mirror, an optical phase array, a liquid crystal waveguide, or a piezo rotating mirror. However, such LIDAR systems may not be sufficiently simple, compact or robust for some applications. Such LIDAR systems may not provide sufficient flexibility, may not provide a sufficient a large field of view, or may not provide sufficient spatial resolution for some applications.

More recently, true solid state (TSS) LIDAR systems have been developed which have no moving parts. For example, TSS LIDAR systems have been developed which include a VCSEL array. For example, referring to FIG. 1, there is shown a prior art illumination system generally designated 2 for a TSS LIDAR system, wherein the illumination system 2 includes a VCSEL array 4 and an electrical driver 6 configured to drive the VCSEL array 4 with one or more electrical signals. The VCSEL array 4 is mounted on a corresponding ceramic heat sink in the form of a ceramic sub-mount 10 so as to provide a thermally-conductive connection between the VCSEL array 4 and the ceramic sub-mount 10. Similarly, the electrical driver 6 is mounted on a corresponding ceramic heat sink in the form of a ceramic sub-mount 12 so as to provide a thermally-conductive connection between the electrical driver 6 and the ceramic sub-mount 12. Each of the ceramic sub-mounts 10, 12 is mounted on a printed circuit board (PCB) 14.

As will be appreciated by one of ordinary skill in the art, the VCSEL array 4 is a top-emitting VCSEL array i.e. the VCSEL array 4 includes a plurality of light emitting surface areas (not shown), one or more light emitting layers (not shown) and a substrate (not shown), wherein the plurality of light emitting surface areas are disposed on an opposite side of the one or more light emitting layers to the substrate. Moreover, the VCSEL array 4 is arranged so that the plurality of light emitting surface areas are defined on an upper surface 20 of the VCSEL array 4. The upper surface 20 of the VCSEL array 4 also includes a plurality of electrical contacts 22. The electrical driver 6 has an upper surface 30 which includes a plurality of electrical contacts 32. The illumination system 2 further includes a plurality of electrically conductive connections between the VCSEL array 4 and the electrical driver 6 in the form of a plurality of wire-bonds 40. This arrangement of the VCSEL array 4 and the electrical driver 6 requires a large number (e.g. hundreds) of wire-bonds between the VCSEL array 4 and the electrical driver 6 to drive each individual segment/row/column of the VCSEL array 4.

However, a large number of wire-bonds results in a high parasitic inductance between the VCSEL array 4 and the electrical driver 6. The higher the parasitic inductance, the longer the optical pulses generated by each VCSEL of the VCSEL array 4 for a given driving voltage. In effect, this may limit the range of a TSS LIDAR system which includes the illumination system 2. Conversely, the higher the parasitic inductance, the larger the driving voltage required for a given speed of modulation of the VCSEL array 4 and a given optical pulse width. However, using a larger driving voltage generates more heat, thereby raising a temperature of the illumination system 2. This may degrade the performance of the VCSEL array 4 and/or the electrical driver 6 and may even lead to failure or damage. Known attempts at dealing with the thermal management problem result in bulky illumination systems having large footprints that are not suitable for incorporation into smaller sensor systems such as smaller LIDAR systems. Moreover, the wire-bonds are fragile and, if damaged, the illumination system 2 may fail.

It should also be understood that the arrangement of the VCSEL array 4 and the electrical driver 6 with the electrical contacts 22 of the VCSEL array 4 and the electrical contacts 32 of the electrical driver 6 arranged at adjacent ends of the VCSEL array 4 and the electrical driver 6 may also require the use of electrically conductive tracks on the upper surface 20 of the VCSEL array 4 and/or the use of electrically conductive tracks on the upper surface 30 of the electrical driver 6. The presence of such electrically conductive tracks on the upper surface 20 of the VCSEL array 4 and/or on the upper surface 30 of the electrical driver 6 may further increase the parasitic inductance between the VCSEL array 4 and the electrical driver 6. This may further increase the width of the optical pulses generated by each VCSEL of the VCSEL array 4 for a given driving voltage thereby further limiting the range of the TSS LIDAR system. Conversely, this may further increase the driving voltage required for a given speed of modulation of the VCSEL array 4 and a given optical pulse width, generating more heat, and further raising the temperature of the illumination system 2.

In view of the foregoing, known TSS LIDAR systems may have limited modulation speeds, may generate too much heat, and/or may not be sufficiently compact or sufficiently robust for some applications. It may also be difficult to integrate safety features into such known TSS LIDAR systems.

### SUMMARY

According to an aspect of the present disclosure there is provided an illumination system comprising:
a support member;
an optical emitter device mounted on the support member;
an electrical driver mounted on the support member; and
one or more electrically conductive connections between the electrical driver and the optical emitter device,
wherein the electrical driver is configured to supply an electrical signal to the optical emitter device via the one or more electrically conductive connections, and wherein the support member comprises a thermally-conductive ceramic material.

Mounting the optical emitter device and the electrical driver on the same support member may allow the optical emitter device and the electrical driver to be disposed closer together thereby reducing the length of the one or more electrical conductive connections that connect the electrical driver and the optical emitter device relative to the length of the one or more electrical conductive connections that connect the electrical driver and the optical emitter device of a known illumination system in which the optical emitter device and the electrical driver are mounted on different support members. Reducing the length of the one or more electrical conductive connections between the electrical driver and the optical emitter device may reduce the inductance between the electrical driver and the optical emitter device relative to the inductance between the electrical driver and the optical emitter device of a known illumination system.

Reducing the inductance between the electrical driver and the optical emitter device may reduce the width of the optical pulses generated by the optical emitter device for a given driving voltage level. In effect, this may increase the range of a TSS LIDAR system which includes the illumination system compared with known TSS LIDAR systems.

Conversely, reducing the inductance between the electrical driver and the optical emitter device may reduce a driving voltage level required for a given speed of modulation of the optical emitter device and a given optical pulse width relative to known illumination systems. Reducing the driving voltage level required may reduce the amount of heat generated or dissipated by the illumination system relative to known illumination systems. Reducing the amount of heat generated or dissipated by the illumination system may simplify the cooling requirements relative to known illumination systems and/or may improve the reliability of the illumination system relative to known illumination systems.

Conversely, reducing the inductance between the electrical driver and the optical emitter device may allow more rapid modulation of the optical emitter device for a given driving voltage level relative to known illumination systems.

Moreover, mounting the optical emitter device and the electrical driver on a thermally-conductive ceramic support member is advantageous because the support member can function as a heat sink and/or may conduct heat away from the optical emitter device and the electrical driver. This may further simplify the cooling requirements relative to known illumination systems and/or may further improve the reliability of the illumination system relative to known illumination systems.

Mounting the optical emitter device and the electrical driver on the same support member may also reduce the number of wire-bonds required to provide the one or more electrically conductive connections between the optical emitter device and the electrical driver compared with the number of wire-bonds required to provide the one or more electrically conductive connections between the optical emitter device and the electrical driver of a known illumination system. This may not only simplify manufacturing of the illumination system, but it may also improve the robustness and reliability of the illumination system.

The thermally-conductive ceramic material may comprise, or be formed from, one or more of: alumina (AI2O3), silicon nitride (Sisl\hat{ }), silicon carbide (SiC), tungsten carbide (WC), a High Temperature Co-fired Ceramic (HTCC) material and a Low Temperature Co-fired Ceramic (LTCC) material.

The optical emitter device may have a thermally-conductive connection to the support member. The use of a thermally-conductive connection between the optical emitter device and the support member may improve the flow of heat from the optical emitter device to the support member.

The illumination system may comprise a thermally-conductive adhesive, glue or filler material disposed between the support member and the optical emitter device for providing or enhancing a thermally-conductive connection between the support member and the optical emitter device.

The electrical driver may have a thermally-conductive connection to the support member. The use of a thermally-conductive connection between the electrical driver and the support member may improve the flow of heat from the electrical driver to the support member.

The illumination system may comprise a thermally-conductive adhesive, glue or filler material disposed between the support member and the electrical driver for providing or enhancing a thermally-conductive connection between the support member and the electrical driver.

The support member may extend between the electrical driver and the optical emitter device. For example, the electrical driver may be mounted on a first side of the support member and the optical emitter device may be mounted on a second side of the support member, wherein the second side of the support member is opposite to the first side of the support member. Mounting the electrical driver and the optical emitter device on opposite sides of the support member may reduce the distance between the electrical driver and the optical emitter device thereby reducing the inductance of any electrical conductive connections, such as any wire-bonds, between the optical driver and the optical emitter device.

The support member may define a space or a recess on the first side of the support member for accommodating the electrical driver. Defining such a space or a recess on the first side of the support member for accommodating the electrical driver may provide a more compact arrangement and reduce the distance between the electrical driver and the optical emitter device thereby reducing the inductance of any electrical conductive connections, such as any wire-bonds, between the optical driver and the optical emitter device. Defining such a space or a recess on the first side of the support member for accommodating the electrical driver may increase the thermal conductivity between the electrical driver and the support member. Defining such a space or a recess on the first side of the support member for accommodating the electrical driver may help to protect the electrical driver from any mechanical damage.

The support member may define a space or a recess on the second side of the support member for accommodating the optical emitter device. Defining such a space or a recess on the second side of the support member for accommodating the optical emitter device may provide a more compact arrangement and reduce the distance between the electrical driver and the optical emitter device thereby reducing the inductance of any electrical conductive connections, such as any wire-bonds, between the optical driver and the optical emitter device. Defining such a space or a recess on the second side of the support member for accommodating the optical emitter device may increase the thermal conductivity between the optical emitter device and the support member. Defining such a space or a recess on the second side of the support member
for accommodating the optical emitter device may help to protect the optical emitter device from any mechanical damage.

The electrical driver and the optical emitter device may at least partially overlap when viewed in a direction which is normal to a light emitting surface of the optical emitter device. The electrical driver and the optical emitter device may be arranged in a stacked configuration.

The electrical driver and the optical emitter device may be vertically integrated. Such arrangements of the electrical driver and the optical emitter device may be more compact, and may therefore benefit from lower inductance, relative to known illumination systems thereby reducing the heat generated and/or improving modulation speeds relative to known illumination systems.

The optical emitter device and the electrical driver may be mounted on the same side of the support member. The support member may define a space or a recess on one side of the support member for accommodating both the optical emitter device and the electrical driver. The support member may define a first space or a first recess on one side of the support member for accommodating the electrical driver and the support member may define a second space or a second recess on the same side of the support member for accommodating the optical emitter device.

The support member may comprise one or more electrical conductors. For example, the support member may comprise one or more electrically-conductive tracks and/or one or more electrically-conductive pads.

One or more of the electrical conductors of the support member may be defined on an outer surface of the support member.

One or more of the electrical conductors of the support member may extend through the support member.

The support member may define one or more apertures, one or more through-holes, one or more vias or one or more channels. Each of one or more of the electrical conductors of the support member may extend through a corresponding aperture, a corresponding through-hole, a corresponding via or a corresponding channel.

The electrical driver may comprise one or more electrically-conductive contacts.

One or more of the electrical conductors of the support member may have an electrically-conductive connection to one or more of the electrically-conductive contacts of the electrical driver.

The electrical driver may be flip-chip bonded to the support member such that one or more of the electrically-conductive contacts of the electrical driver has an electrically-conductive connection to a corresponding electrical conductor of the support member.

The illumination system may comprise an electrically-insulating adhesive, glue or filler material located between the electrical driver and the support member.

Flip-chip bonding the electrical driver to the support member may reduce the distance between the electrical driver and the optical emitter device. This may reduce the inductance between the electrical driver and the optical emitter device. This may simplify manufacturing of the optical emitting system. This may provide a more compact illumination system. This may provide a more robust illumination system. Flip-chip bonding the electrical driver to the support member may avoid any requirement to use wire-bonds, or may at least reduce the number of wire-bonds required, to electrically connect the electrical driver to the optical emitter device. This may reduce the inductance between the electrical driver and the optical emitter device. This may simplify manufacturing of the optical emitting system. This may provide a more compact illumination system. This may provide a more robust illumination system.

Flip-chip bonding the electrical driver to the support member may reduce the distance between the electrical driver and any other electronic components or circuitry external to the electrical driver. This may simplify manufacturing of the optical emitting system. This may provide a more compact illumination system. This may provide a more robust illumination system. Flip-chip bonding the electrical driver to the support member may avoid any requirement to use wire-bonds, or may at least reduce the number of wire-bonds required, to electrically connect the electrical driver to any other electronic components or circuitry external to the electrical driver.

The illumination system may comprise one or more wire-bonds, wherein each wire-bond provides an electrically-conductive connection between an electrically-conductive contact of the electrical driver and a corresponding electrical conductor of the support member. Each of one or more of the wire-bonds may be encapsulated by a protective material, for example a resin such as epoxy resin.

The optical emitter device may comprise one or more electrically-conductive contacts.

One or more of the electrical conductors of the support member may have an electrically-conductive connection to one or more of the electrically-conductive contacts of the optical emitter device.

The optical emitter device may be flip-chip bonded to the support member such that one or more of the electrically-conductive contacts of the optical emitter device has an electrically-conductive connection to a corresponding electrical conductor of the support member.

The illumination system may comprise an electrically-insulating adhesive, glue or filler material located between the optical emitter device and the support member.

Flip-chip bonding the optical emitter device to the support member may reduce the distance between the electrical driver and the optical emitter device. This may reduce the inductance between the electrical driver and the optical emitter device. This may simplify manufacturing of the optical emitting system. This may provide a more compact illumination system. This may provide a more robust illumination system. Flipchip bonding the optical emitter device to the support member may avoid any requirement to use wire-bonds, or may at least reduce the number of wire-bonds required, to electrically connect the electrical driver to the optical emitter device. This may reduce the inductance between the electrical driver and the optical emitter device. This may simplify manufacturing of the optical emitting system. This may provide a more compact illumination system. This may provide a more robust illumination system.

Flip-chip bonding the optical emitter device to the support member may reduce the distance between the optical emitter device and any other electronic components or circuitry external to the optical emitter device. This may simplify manufacturing of the optical emitting system. This may provide a more compact illumination system. This may provide a more robust illumination system. Flip-chip bonding the optical emitter device to the support member may avoid any requirement to use wire-bonds, or may at least reduce the number of wire-bonds required, to electrically connect the optical emitter device to any other electronic components or circuitry external to the optical emitter device.

The illumination system may comprise one or more wire-bonds, wherein each wire-bond provides an electrically-conductive connection between an electrically-conductive contact of the optical emitter device and a corresponding electrical conductor of the support member.

Each of one or more of the wire-bonds may be encapsulated by a protective material, for example a resin such as epoxy resin.

One or more of the electrical conductors of the support member may provide an electrically-conductive connection between the electrical driver and the optical emitter device. This may avoid any requirement to use wire-bonds, or may at least reduce the number of wire-bonds required, to electrically connect the electrical driver to the optical emitter device. This may reduce the inductance between the electrical driver and the optical emitter device. This may simplify manufacturing of the optical emitting system. This may provide a more compact illumination system. This may provide a more robust illumination system.

The illumination system may comprise an electrical interconnection member, wherein the electrical interconnection member defines one or more electrical conductors. For example, the electrical interconnection member may comprise a circuit board such as a printed circuit board (PCB).

The support member may be mounted on the electrical interconnection member.

The support member may have a thermally-conductive connection to the electrical interconnection member.

The first side of the support member may be attached to the electrical interconnection member.

Each of one or more of the electrical conductors of the support member may provide an electrically-conductive connection between the electrical driver and a corresponding electrical conductor of the electrical interconnection member.

Each of one or more of the electrical conductors of the support member may provide an electrically-conductive connection between the optical emitter device and a corresponding electrical conductor of the electrical interconnection member.

The electrical driver may have a thermally-conductive connection to the electrical interconnection member.

The illumination system may comprise a thermally-conductive material disposed between the electrical driver and the electrical interconnection member for providing or enhancing a thermally-conductive connection between the electrical driver and the electrical interconnection member.

The thermally-conductive material disposed between the electrical driver and the electrical interconnection member may comprise any combination of one or more of thermally-conductive adhesive, glue, and filler material.

The electrical driver may have an electrically-conductive connection to the electrical interconnection member.

The illumination system may comprise an electrically-conductive material disposed between the electrical driver and the electrical interconnection member for providing or enhancing an electrically-conductive connection between the electrical driver and the electrical interconnection member.

The electrically-conductive material disposed between the electrical driver and the electrical interconnection member may comprise any combination of one or more of electrically-conductive adhesive, glue, filler material and solder.

The electrical driver may be disposed between the electrical interconnection member and the optical emitter device.

The optical emitter device may be mounted on the support member above the electrical driver with respect to the electrical interconnection member.

The illumination system may comprise a transparent cover member, wherein the cover member is attached to the support member.

The cover member may be transparent to light emitted by the optical emitter device.

The cover member may comprise an anti-reflection (AR) coating for minimising a reflectivity of the cover member with respect to the light emitted by the optical emitter device.

The cover member may be attached to the second side of the support member.

The illumination system may comprise a safety circuit that extends from the electrical driver to the cover member along, or through, the support member.

The electrical driver may be configured to interrupt or switch off the electrical signal used to drive the optical emitter device based on a resistance of the safety circuit and/or an electrical current flowing through the safety circuit. Use of such a safety circuit may avoid accidental or inadvertent operation of the optical emitter device in the event of the cover member becoming detached or separated from the support member.

The optical emitter device may comprise a surface-emitting optical emitter device. The optical emitter device may comprise a Vertical Cavity Surface Emitting Laser (VCSEL).

The optical emitter device may be configured to emit visible and/or infra-red light.

The optical emitter device may comprise one or more light emitting layers and a substrate, wherein the one or more light emitting layers are disposed on the substrate.

The optical emitter device may be a top-emitting optical emitter device i.e. wherein the optical emitter device may be configured to emit light through a light emitting surface which is disposed on an opposite side of the one or more light emitting layers to the substrate.

The optical emitter device may be a bottom-emitting optical emitter device i.e. the optical emitter device may be configured to emit light through the substrate.

The illumination system may comprise a plurality of optical emitter devices.

One or more of the optical emitter devices may comprise a surface-emitting optical emitter device.

The plurality of optical emitter devices may comprise an array of optical emitter devices, for example an integrated array of optical emitter devices.

The array of optical emitter devices may comprise a 2D array of optical emitter devices, such as a uniform 2D array of optical emitter devices.

The array of optical emitter devices may comprise a non-addressable array of optical emitter devices.

The array of optical emitter devices may comprise an addressable array of optical emitter devices, for example wherein one or more subsets of one or more of the optical emitter devices are addressable independently of one or more other subsets of one or more other optical emitter devices.

One or more of the optical emitter devices may comprise a VCSEL.

The array of optical emitter devices may comprise a VCSEL array.

One or more of the optical emitter devices may be configured to emit visible and/or infra-red light.

One or more of the optical emitter devices may comprise one or more light emitting layers and a substrate, wherein the one or more light emitting layers are disposed on the substrate.

One or more of the optical emitter devices may be configured to emit light through a light emitting surface which is on an opposite side of the one or more light emitting layers to the substrate i.e. wherein one or more of the optical emitter devices may be a top-emitting optical emitter device.

One or more of the optical emitter devices may be configured to emit light through a light emitting surface which is on the same side of the one or more light emitting layers as the substrate i.e. wherein one or more of the optical emitter devices may be a bottom emitting optical emitter device which is configured to emit light through the substrate.

The illumination system may be configured for use as an illumination system or an optical transmitter system for use in a sensing system such as a 3D sensing system, or a LIDAR system.

According to an aspect of the present disclosure there is provided a sensing system such as a 3D sensing system or a LIDAR system, comprising the illumination system as described above.

The sensing system may comprise an optical receiver system, wherein the optical receiver system is configured to generate an electrical signal which is representative of a power of an optical signal received by the optical receiver system. The electrical driver may be configured to control the electrical signal used to drive the optical emitter device according to the electrical signal generated by the optical receiver system.

The optical signal received by the optical receiver system may comprise an optical signal which is emitted by the illumination system, transmitted from the illumination system to an object in a scene to be sensed and directed, for example reflected or scattered, from the object to the optical receiver system. Controlling the electrical signal used to drive the optical emitter device in this way may be used to automatically control a gain of the sensing system.

The optical signal received by the optical receiver system may be representative of ambient light in a scene to be sensed. Controlling the electrical signal used to drive the optical emitter device in this way may be used to automatically control an optical power of the light emitted by the illumination system according to ambient conditions, for example to improve a signal-to-noise ratio of the sensing system.

According to an aspect of the present disclosure there is provided a method of operating a sensing system, the method comprising:
using an optical receiver system to generate an electrical signal which is representative of a power of an optical signal received by the optical receiver system; and
controlling an electrical signal used to drive an optical emitter device according to the electrical signal generated by the optical receiver system.

The optical signal received by the optical receiver system may comprise an optical signal which is emitted by the illumination system, transmitted from the illumination system to an object in a scene to be sensed and directed, for example reflected or scattered, from the object to the optical receiver system.

The optical signal received by the optical receiver system may be representative of ambient light in a scene to be sensed.

According to an aspect of the present disclosure there is provided a method of manufacturing an illumination system, the method comprising:
mounting an optical emitter device and an electrical driver on a support member, and
connecting the electrical driver and the optical emitter device using one or more electrically conductive connections,
wherein the electrical driver is configured to supply an electrical signal to the optical emitter device via the one or more electrically conductive connections, and wherein the support member comprises a thermally-conductive ceramic material.

The thermally-conductive ceramic material may comprise, or be formed from, one or more of alumina (AI2O3), silicon nitride (SislSk), silicon carbide (SiC), tungsten carbide (WC), a High Temperature Co-fired Ceramic (HTCC) material and a Low Temperature Co-fired Ceramic (LTCC) material.

It should be understood that any one or more of the features of any one of the foregoing aspects of the present disclosure may be combined with any one or more of the features of any of the other foregoing aspects of the present disclosure. In particular, any one or more of the features of the illumination system may be combined with any one or more of the features of the method of operating the illumination system or any one or more of the features of the method of manufacturing the illumination system.

### BRIEF DESCRIPTION OF THE DRAWINGS

An illumination system for a sensing system such as a 3D sensing system or a LIDAR system, a 3D sensing system or a LIDAR system, and associated methods, will now be described by way of non-limiting example only with reference to the accompanying drawings of which:

FIG. 1 is a schematic of a prior art illumination system;

FIG. 2 is a schematic of a first illumination system;

FIG. 3 is a schematic of a second illumination system;

FIG. 4 is a schematic of a third illumination system;

FIG. 5 is a schematic of a fourth illumination system;

FIG. 6 is a schematic of a fifth illumination system;

FIG. 7 is a schematic of a sixth illumination system; and

FIG. 8 is a schematic of LIDAR system.

### DETAILED DESCRIPTION OF THE DRAWINGS

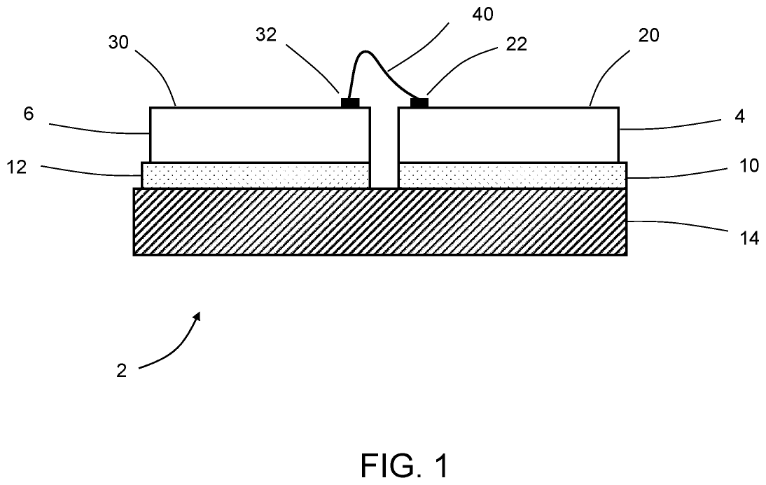

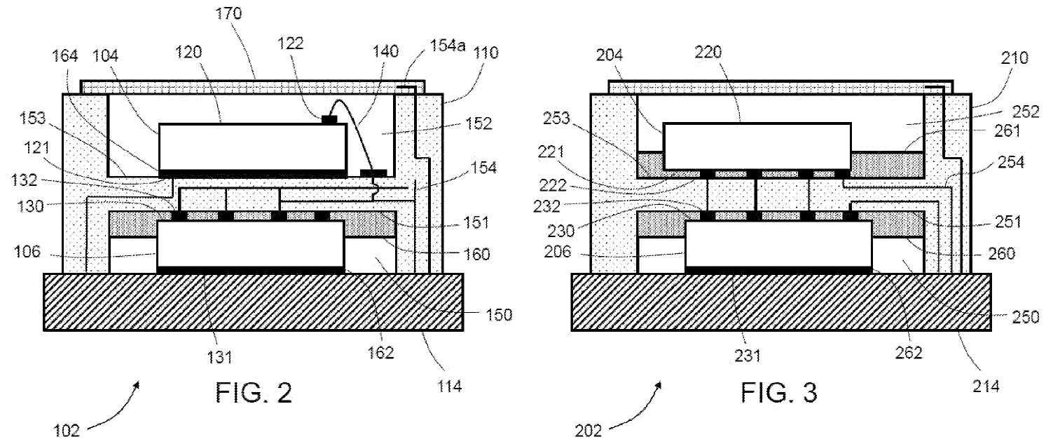

Referring initially to FIG. 2, there is shown a first illumination system generally designated 102 for a LIDAR system. The illumination system 102 of FIG. 2 includes some features which correspond closely to features of the illumination system 2 of FIG. 1, with the relevant features of the illumination system 102 of FIG. 2 being represented by the same reference numerals as like features of the illumination system 2 of FIG. 1 incremented by “100”. Like the illumination system 2 of FIG. 1, the illumination system 102 of FIG. 2 includes a support member in the form of a ceramic sub-mount 110, an optical emitter device in the form of a VCSEL array 104, an electrical driver 106 and one or more electrically conductive connections between the electrical driver 106 and the VCSEL array 104. However, unlike the illumination system 2 of FIG. 1, in the illumination system 102 of FIG. 2 the VCSEL array 104 and the electrical driver 106 are both mounted on the same ceramic sub-mount 110.

As will be described in more detail below, the electrical driver 106 is configured to supply an electrical signal to the VCSEL array 104 via the one or more electrically conductive connections. The illumination system 102 further includes an electrical interconnection member in the form of a PCB 114, wherein the ceramic sub-mount 110 is mounted on the PCB 114 using a thermally-conductive material (not shown) such as a thermally-conductive adhesive, a thermally-conductive glue, a thermally-conductive epoxy, a thermally-conductive solder or the like so as to provide a thermally-conductive connection between the ceramic sub-mount 110 and the PCB 114.

Moreover, as will be appreciated from FIG. 2, the VCSEL array 104 and the electrical driver 106 are vertically integrated in a stacked configuration with the VCSEL array 104 disposed above the electrical driver 106, and a horizontal portion of the ceramic sub-mount 110 located between the VCSEL array 104 and the electrical driver 106. As will also be appreciated by one of ordinary skill in the art, the VCSEL array 104 is a top-emitting VCSEL array having a plurality of light emitting surface areas defined on an upper surface 120 of the VCSEL array 104. The VCSEL array 104 further includes a plurality of electrical contacts 122 on the upper surface 120 thereof. Similarly, the electrical driver 106 includes a plurality of electrical contacts 132 on an upper surface 130 thereof.

A first, lower side of the ceramic sub-mount 110 defines a first, downwardly-disposed recess 150 for accommodating the electrical driver 106, the first recess 150 defining a downwardly-disposed surface 151. A second, upper side of the ceramic submount 110 defines a second, upwardly-disposed recess 152 for accommodating the VCSEL array 104, the second recess 152 defining an upwardly-disposed surface 153. The ceramic sub-mount 110 further includes a plurality of electrical conductors 154 in the form of one or more electrically conductive tracks and/or one or more electrically-conductive pads which are defined on an outer surface of the ceramic sub-mount 110 and/or which extend through the ceramic sub-mount 110.

The electrical driver 106 is mounted on the ceramic sub-mount 110 in the first recess 150. Specifically, the upper surface 130 of the electrical driver 106 is flip-chip bonded to the downwardly disposed surface 151 of the ceramic sub-mount 110 in the first recess 150 such that one or more of the electrically-conductive contacts 132 of the electrical driver 106 has an electrically-conductive connection to a corresponding
electrical conductor 154 of the ceramic sub-mount 110. The illumination system 102 further includes an electrically-insulating thermally-conductive filler material 160 in the form of an electrically-insulating thermally-conductive adhesive, glue, or epoxy located between the upper surface 130 of the electrical driver 106 and the downwardly disposed surface 151 of the ceramic sub-mount 110. As will be understood by one of ordinary skill in the art, the electrically-insulating thermally-conductive filler material 160 not only serves to strengthen the bond between the electrical driver 106 and the ceramic submount 110 for improved robustness and to reduce any stresses caused as a result of any mismatch of the coefficients of thermal expansion (CTEs) between the electrical driver 106 and the ceramic sub-mount 110, but the electrically-insulating thermally-conductive filler material 160 also serves to conduct heat from the electrical driver 106 to the ceramic sub-mount 110.

Depending on the thickness of the electrical driver 106 and the geometry of the first recess 150, the lower surface 131 of the electrical driver 106 may also be bonded to the PCB 114 using a thermally-conductive material 162 such as a thermally-conductive adhesive, a thermally-conductive glue, a thermally-conductive epoxy, a thermally-conductive solder or the like to allow the conduction of heat from the electrical driver 106 directly to the PCB 114.

The VCSEL array 104 is mounted on the ceramic sub-mount 110 in the second recess 152. Specifically, a lower surface 121 of the VCSEL array 104 is bonded to the upwardly disposed surface 153 of the ceramic sub-mount 110 in the second recess 152 using a thermally-conductive material 164 such as thermally-conductive adhesive, glue, epoxy or the like located between the upwardly disposed surface 153 of the ceramic submount 110 and the lower surface 121 of the VCSEL array 104.

The illumination system 102 further includes a plurality of electrically conductive connections between the electrical contacts 122 on the upper surface 120 of the VCSEL array 104 and the plurality of electrical conductors 154 of the ceramic sub-mount 110. Specifically, the illumination system 102 further includes a plurality of wire-bonds 140 between the electrical contacts 122 on the upper surface 120 of the VCSEL array 104 and the plurality of electrical conductors 154 of the ceramic sub-mount 110.

The illumination system 102 further includes a transparent cover member 170 attached to the second, upper side of the ceramic sub-mount 110 so as to cover an open end of the second, upwardly-disposed recess 152. The cover member 170 comprises an anti-reflection (AR) coating for minimising a reflectivity of the cover member 170 with respect to the light emitted by the VCSEL array 104. Moreover, one or more of the electrical conductors 154 of the ceramic sub-mount 110 define a safety circuit 154a that extends from the electrical driver 106 along, or through, the ceramic sub-mount 110 to the cover member 170.

In use, the electrical driver 106 drives the VCSEL array 104 with one or more electrical signals such as one or more electrical currents via the plurality of electrical conductors 154 of the ceramic sub-mount 110 and the plurality of wire-bonds 140 causing the VCSEL array 104 to emit light through the upper surface 120 of the VCSEL array 104 and through the cover member 170.

From the foregoing description, it will be understood that mounting the VCSEL array 104 and the electrical driver 106 on the same ceramic sub-mount 110 allows the VCSEL array 104 and the electrical driver 106 to be disposed closer together thereby reducing the length of the electrical conductors that connect the electrical driver 106 and the VCSEL array 104 relative to the wire-bonds 40 that connect the electrical driver 6 and the VCSEL array 4 of the known illumination system 2 of FIG. 1 in which the VCSEL array 4 and the electrical driver 6 are mounted on different ceramic sub-mounts 10 and 12 respectively. In this regard, it should be understood that FIGS. 1 and 2 are schematic in nature and that, in reality, the relative proportions of different features of the illumination systems 2, 102 may be quite different to the relative proportions of the features of the illumination systems 2, 102 shown in FIGS. 1 and 2. In particular, it should be understood that the thicknesses of the VCSEL arrays 4, 104 and the electrical drivers 6 106 have been greatly exaggerated in FIGS. 1 and 2 in the interests of clarity and that, in reality, the thicknesses of the VCSEL arrays 4, 104 and the electrical drivers 6, 106 would be much reduced relative to the other dimensions of the VCSEL arrays 4, 104 and the electrical drivers 6, 106 shown in FIGS. 1 and 2. Similarly, in reality, the horizontal separation between the VCSEL array 4 and the electrical driver 6 of the illumination system 2 of FIG. 1 would be much greater than the vertical separation between the VCSEL array 104 and the electrical driver 106 of the illumination system 102 of FIG. 2. In addition, although the electrical contacts 22 of the VCSEL array 4 and the electrical contacts 32 of the electrical driver 6 are positioned at adjacent ends of the VCSEL array 4 and the electrical driver 6 of the illumination system 2 of FIG. 1, this requires that electrically conductive tracks extend across the upper surface 20 of the VCSEL array 4 and that electrically conductive tracks extend across the upper surface 20 of the electrical driver 6 so that the total length of any electrically conductive connection between the electrical driver 6 and any VCSEL of the VCSEL array 4 of the illumination system 2 of FIG. 1 is greater than the total length of any electrically conductive connection between the electrical driver 106 and any VCSEL of the VCSEL array 104 of the illumination system 102 of FIG. 2.

Reducing the length of the electrical conductors connecting the electrical driver 106 and the VCSEL array 104 reduces the inductance between the electrical driver 106 and the VCSEL array 104 relative to known illumination systems. Reducing the inductance between the electrical driver 106 and the VCSEL array 104 may reduce the optical pulse widths that may be generated by each VCSEL of the VCSEL array 104 for a given driving voltage level, thereby increasing the range of a TSS LIDAR system which includes the illumination system 102 of FIG. 2. Conversely, reducing the inductance between the electrical driver 106 and the VCSEL array 104 may reduce the driving voltage level required for a given speed of modulation of the VCSEL array 104 and a given optical pulse width relative to known illumination systems. Reducing the driving voltage level required reduces the amount of heat generated or dissipated by the illumination system 102 relative to known illumination systems. Reducing the amount of heat generated or dissipated by the illumination system 102 also simplifies the cooling requirements relative to known illumination systems and improves the reliability of the illumination system 102 relative to known illumination systems.

Conversely, reducing the inductance between the electrical driver 106 and the VCSEL array 104 may allow more rapid modulation of the VCSEL array 104 for a given driving voltage level relative to known illumination systems.

In addition, reducing the length of the electrical conductors connecting the electrical driver 106 and the VCSEL array 104 may reduce the overall size of the illumination system 102 relative to the size of known illumination systems.

Moreover, mounting the VCSEL array 104 and the electrical driver 106 on the thermally-conductive ceramic sub-mount 110 is advantageous because the ceramic submount 110 can function as a heat sink and/or may conduct heat away from the VCSEL array 104 and the electrical driver 106. This may further simplify the cooling requirements relative to known illumination systems and/or may further improve the reliability of the illumination system 102 relative to known illumination systems.

Furthermore, since the safety circuit 154a extends from the ceramic sub-mount 110 to the cover member 170, in the event that the cover member 170 should become detached from the ceramic sub-mount 110, the safety circuit 154a is broken. This may result in a significant change in the resistance of the safety circuit 154a and/or in the electrical current flowing through the safety circuit 154a which is/are detected by the electrical driver 106. The electrical driver 106 detects the change in the resistance of the safety circuit 154a and/or the change in the electrical current flowing through the safety circuit 154a and interrupts, switches off or prevents the transmission of any electrical signals from the electrical driver 106 to the VCSEL array 104.

Referring to FIG. 3, there is shown a second illumination system generally designated 202 for a LIDAR system. The illumination system 202 of FIG. 3 includes many features which correspond closely to the features of the illumination system 102 of FIG. 2, with features of the illumination system 202 of FIG. 3 being represented by the same reference numerals as the like features of the illumination system 102 of FIG. 2 incremented by “100”. Like the illumination system 102 of FIG. 2, the illumination system 202 of FIG. 3 includes a support member in the form of a ceramic sub-mount 210. The illumination system 202 includes an optical emitter device in the form of a VCSEL array 204 mounted on the ceramic sub-mount 210, an electrical driver 206 mounted on the ceramic sub-mount 210, and one or more electrically conductive connections between the electrical driver 206 and the VCSEL array 204. The electrical driver 206 is configured to supply an electrical signal to the VCSEL array 204 via the one or more electrically conductive connections. The illumination system 202 further includes an electrical interconnection member in the form of a PCB 214, wherein the ceramic sub-mount 210 is mounted on the PCB 214 using a thermally-conductive material (not shown) such as a thermally-conductive adhesive, a thermally-conductive glue, a thermally-conductive epoxy, a thermally-conductive solder or the like so as to provide a thermally-conductive connection between the ceramic sub-mount 210 and the PCB 214.

Like the illumination system 102 of FIG. 2, the VCSEL array 204 and the electrical driver 206 are vertically integrated in a stacked configuration with the VCSEL array 204 disposed above the electrical driver 206, and a horizontal portion of the ceramic submount 210 located between the VCSEL array 204 and the electrical driver 206.

Like the illumination system 102 of FIG. 2, a first, lower side of the ceramic submount 210 defines a first, downwardly-disposed recess 250 for accommodating the electrical driver 206, the first recess 250 defining a downwardly disposed surface 251. A second, upper side of the ceramic sub-mount 210 defines a second, upwardly-disposed recess 252 for accommodating the VCSEL array 204, the second recess 252 defining an upwardly disposed surface 253. The ceramic sub-mount 210 further includes a plurality of electrical conductors 254 in the form of one or more electrically conductive tracks and/or one or more electrically-conductive pads which are defined on an outer surface of the ceramic sub-mount 210 and/or which extend through the ceramic submount 210.

The electrical driver 206 is mounted on the ceramic sub-mount 210 in the first recess 250. Specifically, the upper surface 230 of the electrical driver 106 is flip-chip bonded to the downwardly disposed surface 251 of the ceramic sub-mount 210 in the first recess 250 such that one or more of the electrically-conductive contacts 232 of the electrical driver 206 has an electrically-conductive connection to a corresponding electrical conductor 254 of the ceramic sub-mount 210. The illumination system 202 further includes an electrically-insulating thermally-conductive filler material 260 in the form of an electrically-insulating thermally-conductive adhesive, glue, or epoxy located between the upper surface 230 of the electrical driver 206 and the downwardly disposed surface 251 of the ceramic sub-mount 210. As will be understood by one of ordinary skill in the art, the electrically-insulating thermally-conductive filler material 260 not only serves to strengthen the bond between the electrical driver 206 and the ceramic submount 210 for improved robustness and to reduce any stresses caused as a result of any mismatch of the coefficients of thermal expansion (CTEs) between the electrical driver 206 and the ceramic sub-mount 210, but the electrically-insulating thermally-conductive filler material 260 also serves to conduct heat from the electrical driver 206 to the ceramic sub-mount 210.

Depending on the thickness of the electrical driver 206 and the geometry of the first recess 250, the lower surface 231 of the electrical driver 206 may also be bonded to the PCB 214 using a thermally-conductive material 262 such as a thermally-conductive adhesive, a thermally-conductive glue, a thermally-conductive epoxy, a thermally-conductive solder or the like to allow the conduction of heat from the electrical driver 206 directly to the PCB 214.

Like the illumination system 102 of FIG. 2, the VCSEL array 204 is mounted on the ceramic sub-mount 210 in the second recess 252. However, unlike the illumination system 102 of FIG. 2, the VCSEL array 204 is configured to emit light through a substrate of the VCSEL array and the VCSEL array 204 is flip-chip bonded to the ceramic submount 210 such that a light emitting surface 220 of the substrate of the VCSEL array 204 is directed upwardly. The VCSEL array 204 further includes a plurality of electrical contacts 222 on a lower surface 221 thereof. The lower surface 221 of the VCSEL array 204 is flip-chip bonded to the upwardly disposed surface 253 of the ceramic sub-mount 210 in the upwardly-disposed recess 252 such that one or more of the electrically-conductive contacts 222 of the VCSEL array 204 has an electrically-conductive connection to a corresponding electrical conductor 254 of the ceramic sub-mount 210.

The illumination system 202 further includes an electrically-insulating thermally-conductive filler material 261 in the form of an electrically-insulating thermally-conductive adhesive, glue, or epoxy located between the lower surface 221 of the VCSEL array 204 and the upwardly disposed surface 253 of the ceramic sub-mount 210. As will be understood by one of ordinary skill in the art, the electrically-insulating thermally-conductive filler material 261 not only serves to strengthen the bond between the VCSEL array 204 and the ceramic sub-mount 210 for improved robustness and to reduce any stresses caused as a result of any mismatch of the coefficients of thermal expansion (CTEs) between the VCSEL array 204 and the ceramic sub-mount 210, but the electrically-insulating thermally-conductive filler material 261 also serves to conduct heat from the VCSEL array 204 to the ceramic sub-mount 210.

As a consequence of flip-chip bonding both the electrical driver 206 and the VCSEL array 204 to the ceramic sub-mount 210, the plurality of electrical conductors 254 of the ceramic sub-mount 210 provide a plurality of electrically conductive connections between the electrical contacts 232 on the upper surface 230 of the electrical driver 206 and the electrical contacts 222 on the lower surface 221 of the VCSEL array 204. Consequently, not only are the length of the electrically conductive connections between the electrical driver 206 and the VCSEL array 204 reduced relative to the length of the electrically conductive connections between the electrical driver and the VCSEL array of a prior art illumination system, but the use of wire-bonds is not required. Consequently, the inductance between the electrical driver 206 and the VCSEL array 204 is reduced. Reducing the inductance between the electrical driver 206 and the VCSEL array 204 may reduce the optical pulse widths that may be generated by each VCSEL of the VCSEL array 204 for a given driving voltage level, thereby increasing the range of a TSS LIDAR system which includes the illumination system 202 of FIG. 3. Conversely, reducing the inductance between the electrical driver 206 and the VCSEL array 204 may reduce a driving voltage level required for a given speed of modulation of the VCSEL array 204 and a given optical pulse width relative to known illumination systems. Reducing the driving voltage level required reduces the amount of heat generated or dissipated by the illumination system 202 relative to known illumination systems. Reducing the amount of heat generated or dissipated by the illumination system 202 also simplifies the cooling requirements relative to known illumination systems and improves the reliability of the illumination system 202 relative to known illumination systems.

Conversely, reducing the inductance between the electrical driver 206 and the VCSEL array 204 may allow more rapid modulation of the VCSEL array 204 for a given driving voltage level relative to known illumination systems.

In addition, reducing the length of the electrical conductors connecting the electrical driver 206 and the VCSEL array 204 may reduce the overall size of the illumination system 202 relative to the size of known illumination systems.

In other respects, the structure and functionality of the illumination system 202 of FIG. 3 is similar to the structure and functionality of the illumination system 102 of FIG. 2.

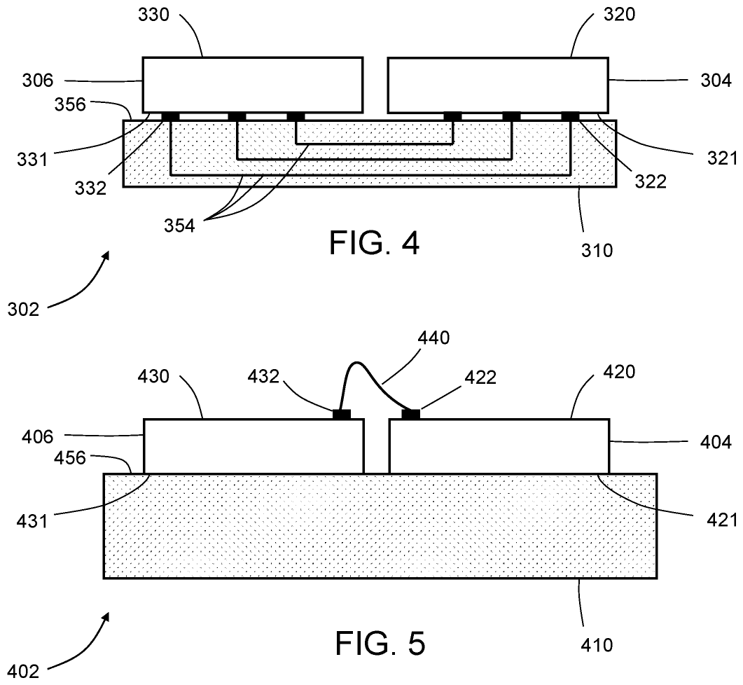

Referring to FIG. 4, there is shown a third illumination system generally designated 302 for a LIDAR system. The illumination system 302 of FIG. 4 includes many features which correspond closely to the features of the illumination system 202 of FIG. 3, with features of the illumination system 302 of FIG. 4 being represented by the same reference numerals as the like features of the illumination system 202 of FIG. 3 incremented by “100”. Like the illumination system 202 of FIG. 3, the illumination system 302 of FIG. 4 includes a support member in the form of a ceramic sub-mount 310. The illumination system 302 includes an optical emitter device in the form of a VCSEL array 304 mounted on the ceramic sub-mount 310, an electrical driver 306 mounted on the ceramic sub-mount 310, and one or more electrically conductive connections between the electrical driver 306 and the VCSEL array 304. The electrical driver 306 is configured to supply an electrical signal to the VCSEL array 304 via the one or more electrically conductive connections.

Like the ceramic sub-mount 210 of the illumination system 202 of FIG. 3, the ceramic sub-mount 310 of the illumination system 302 of FIG. 4 includes or defines a plurality of electrical conductors 354 which extend along a surface and/or through the ceramic sub-mount 310.

However, unlike the ceramic sub-mount 210 of the illumination system 202 of FIG. 3, the ceramic sub-mount 310 of the illumination system 302 of FIG. 4 comprises a sheet of ceramic material, wherein the electrical driver 306 and the VCSEL array 304 are both mounted on the same side of the ceramic sub-mount 310.

Specifically, a lower surface 331 of the electrical driver 306 is flip-chip bonded to an upper surface 356 of the ceramic sub-mount 310 such that one or more electrically-conductive contacts 332 of the electrical driver 306 has an electrically-conductive connection to a corresponding electrical conductor 354 of the ceramic sub-mount 310. Although not shown in FIG. 4, the illumination system 302 may further include an electrically-insulating thermally-conductive filler material in the form of an electrically-insulating thermally-conductive adhesive, glue, or epoxy located between the lower surface 331 of the electrical driver 306 and the upper surface 356 of the ceramic submount 310.

Like the VCSEL array 204 of the illumination system 202 of FIG. 3, the VCSEL array 304 of the illumination system 302 of FIG. 4 is configured to emit light through a substrate of the VCSEL array 304 and the VCSEL array 304 is flip-chip bonded to the upper surface 356 of the ceramic sub-mount 310 alongside the electrical driver 306 such that a light emitting surface 320 of the substrate of the VCSEL array 304 is directed upwardly. The VCSEL array 304 further includes a plurality of electrical contacts 322 on a lower surface 321 thereof. The lower surface 321 of the VCSEL array 304 is flip-chip bonded to the upper surface 356 of the ceramic sub-mount 310 such that one or more of the electrically-conductive contacts 322 of the VCSEL array 304 has an electrically-conductive connection to a corresponding electrical conductor 354 of the ceramic submount 310. Although not shown in FIG. 4, the illumination system 302 may further include an electrically-insulating thermally-conductive filler material in the form of an electrically-insulating thermally-conductive adhesive, glue, or epoxy located between the lower surface 321 of the VCSEL array 304 and the upper surface 356 of the ceramic sub-mount 310.

As a consequence of flip-chip bonding both the electrical driver 306 and the VCSEL array 304 to the ceramic sub-mount 310, the plurality of electrical conductors 354 of the ceramic sub-mount 310 provide a plurality of electrically conductive connections between the electrical contacts 332 on the lower surface 331 of the electrical driver 306 and the electrical contacts 322 on the lower surface 321 of the VCSEL array 304. Consequently, not only are the length of the electrically conductive connections between the electrical driver 306 and the VCSEL array 304 reduced relative to the length of the electrically conductive connections between the electrical driver and the VCSEL array of a prior art illumination system, but the use of wire-bonds is not required. Consequently, the inductance between the electrical driver 306 and the VCSEL array 304 is reduced. Reducing the inductance between the electrical driver 306 and the VCSEL array 304 may reduce the optical pulse widths that may be generated by each VCSEL of the VCSEL array 304 for a given driving voltage level, thereby increasing the range of a TSS LIDAR system which includes the illumination system 302 of FIG. 4. Conversely, reducing the inductance between the electrical driver 306 and the VCSEL array 304 may reduce a driving voltage level required for a given speed of modulation of the VCSEL array 304 and a given optical pulse width relative to known illumination systems. Reducing the driving voltage level required reduces the amount of heat generated or dissipated by the illumination system 302 relative to known illumination systems. Reducing the amount of heat generated or dissipated by the illumination system 302 also simplifies the cooling requirements relative to known illumination systems and improves the reliability of the illumination system 302 relative to known illumination systems.

Conversely, reducing the inductance between the electrical driver 306 and the VCSEL array 304 may allow more rapid modulation of the VCSEL array 304 for a given driving voltage level relative to known illumination systems.

In addition, reducing the length of the electrical conductors connecting the electrical driver 306 and the VCSEL array 304 may reduce the overall size of the illumination system 302 relative to the size of known illumination systems.

In other respects, the structure and functionality of the illumination system 302 of FIG. 4 is similar to the structure and functionality of the illumination system 202 of FIG. 3.

Referring to FIG. 5, there is shown a fourth illumination system generally designated 402 for a LIDAR system. The illumination system 402 of FIG. 5 includes many features which correspond closely to the features of the illumination system 302 of FIG. 4, with features of the illumination system 402 of FIG. 5 being represented by the same reference numerals as the like features of the illumination system 302 of FIG. 4 incremented by “100”. Like the illumination system 302 of FIG. 4, the illumination system 402 of FIG. 5 includes a support member in the form of a ceramic sub-mount 410. The illumination system 402 includes an optical emitter device in the form of a VCSEL array 404 mounted on the ceramic sub-mount 410, an electrical driver 406 mounted on the ceramic sub-mount 410, and one or more electrically conductive connections between the electrical driver 406 and the VCSEL array 404. The electrical driver 406 is configured to supply an electrical signal to the VCSEL array 404 via the one or more electrically conductive connections.

Like the ceramic sub-mount 310 of the illumination system 302 of FIG. 4, the ceramic sub-mount 410 comprises a sheet of ceramic material, wherein the electrical driver 406 and the VCSEL array 404 are both mounted on the same side of the ceramic sub-mount 410.

Specifically, a lower surface 431 of the electrical driver 406 is bonded to an upper surface 456 of the ceramic sub-mount 410 using a thermally-conductive material (not shown) such as a thermally-conductive adhesive, a thermally-conductive glue, a thermally-conductive epoxy or the like.

Similarly, a lower surface 421 of the VCSEL array 404 is bonded to the upper surface 456 of the ceramic sub-mount 410 using a thermally-conductive material (not shown) such as a thermally-conductive adhesive, a thermally-conductive glue, a thermally-conductive epoxy, or the like. Like the VCSEL array 304 of the illumination system 302 of FIG. 4, the VCSEL array 404 of the illumination system 402 of FIG. 5 is configured to emit light through a substrate of the VCSEL array 404 and the VCSEL array 404 is bonded to the upper surface 456 of the ceramic sub-mount 410 alongside the electrical driver 406 such that a light emitting surface 420 of the substrate of the VCSEL array 404 is directed upwardly.

One or more electrically-conductive connections are provided in the form of one or more wire-bonds 440 between one or more electrically-conductive contacts 432 of the electrical driver 406 and one or more electrically-conductive contacts 422 the VCSEL array 404. As a consequence of bonding both the electrical driver 406 and the VCSEL array 404 on the same upper side 456 of the same ceramic sub-mount 410, the length of the wire-bonds 440 may be reduced relative to the length of the wire-bonds of known illumination systems. Consequently, the inductance between the electrical driver 406 and the VCSEL array 404 is reduced. Reducing the inductance between the electrical driver 406 and the VCSEL array 404 may reduce the optical pulse widths that may be generated by each VCSEL of the VCSEL array 404 for a given driving voltage level, thereby increasing the range of a TSS LIDAR system which includes the illumination system 402 of FIG. 5. Conversely, reducing the inductance between the electrical driver 406 and the VCSEL array 404 may reduce a driving voltage level required for a given speed of modulation of the VCSEL array 404 and a given optical pulse width relative to known illumination systems. Reducing the driving voltage level required reduces the amount of heat generated or dissipated by the illumination system 402 relative to known illumination systems. Reducing the amount of heat generated or dissipated by the illumination system 402 also simplifies the cooling requirements relative to known illumination systems and improves the reliability of the illumination system 402 relative to known illumination systems.

Conversely, reducing the inductance between the electrical driver 406 and the VCSEL array 404 may allow more rapid modulation of the VCSEL array 404 for a given driving voltage level relative to known illumination systems.

In other respects, the structure and functionality of the illumination system 402 of FIG. 5 is similar to the structure and functionality of the illumination system 302 of FIG. 4.

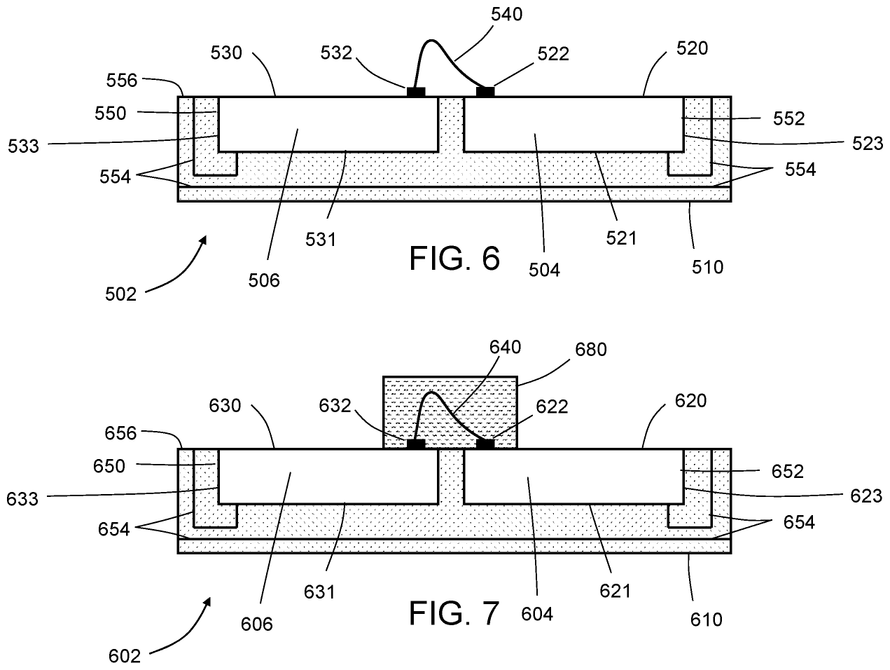

Referring to FIG. 6, there is shown a fifth illumination system generally designated 502 for a LIDAR system. The illumination system 502 of FIG. 6 includes many features which correspond closely to the features of the illumination system 402 of FIG. 5, with features of the illumination system 502 of FIG. 6 being represented by the same reference numerals as the like features of the illumination system 402 of FIG. 5 incremented by “100”. Like the illumination system 402 of FIG. 5, the illumination system 502 of FIG. 6 includes a support member in the form of a ceramic sub-mount 510. The illumination system 502 also includes an optical emitter device in the form of a VCSEL array 504 mounted on the ceramic sub-mount 510, an electrical driver 506 mounted on the ceramic sub-mount 510, and one or more electrically conductive connections between the electrical driver 506 and the VCSEL array 504. The electrical driver 506 is configured to supply an electrical signal to the VCSEL array 504 via the one or more electrically conductive connections.

However, unlike the ceramic sub-mount 410 of the illumination system 402 of FIG. 4, the ceramic sub-mount 510 defines a first upwardly-directed recess 550 in an upper surface 556 of the ceramic sub-mount 510 and a second upwardly-directed recess 552 in the upper surface 556 of the ceramic sub-mount 510. The ceramic sub-mount 510 further includes one or more electrical conductors 554 in the form of one or more electrically conductive tracks which extend along an outer surface of the ceramic submount 510 and/or through the ceramic sub-mount 510.

The electrical driver 506 is located in first upwardly-directed recess 550. A lower surface 531 of the electrical driver 506 is bonded to the bottom of the upwardly-directed recess 550 using a thermally- and electrically-conductive material (not shown) such as a thermally- and electrically-conductive adhesive, a thermally- and electrically-conductive glue, a thermally- and electrically-conductive epoxy, a thermally- and electrically-conductive solder, or the like so as to form an electrically conductive connection to one or more of the electrical conductors 554 of the ceramic sub-mount 510. The sides 533 of the electrical driver 506 may also be bonded to the sidewalls of the upwardly-directed recess 550 using a thermally-conductive material (not shown) such as a thermally-conductive adhesive, a thermally-conductive glue, a thermally-conductive epoxy, or the like to improve the conduction of heat from the sides 533 of the electrical driver 506 to the ceramic sub-mount 510. Depending on the configuration of the electrical driver 506, the thermally-conductive material used to bond the sides 533 of the electrical driver 506 to the sidewalls of the upwardly-directed recess 550, may also be electrically-conductive.

Similarly, the VCSEL array 504 is located in second upwardly-directed recess 552 in the upper surface 556 of the ceramic sub-mount 510. A lower surface 521 of the VCSEL array 504 is bonded to the bottom of the upwardly-directed recess 552 using a thermally- and electrically-conductive material (not shown) such as a thermally- and electrically-conductive adhesive, a thermally- and electrically-conductive glue, a thermally- and electrically-conductive epoxy, a thermally- and electrically-conductive solder, or the like so as to form an electrically conductive connection to one or more of the electrical conductors 554 of the ceramic sub-mount 510. The sides 523 of the VCSEL array 504 may also be bonded to the sidewalls of the upwardly-directed recess 552 using a thermally-conductive material (not shown) such as a thermally-conductive adhesive, a thermally-conductive glue, a thermally-conductive epoxy, or the like to improve the conduction of heat from the sides 523 of the VCSEL array 504 to the ceramic sub-mount 510. Depending on the configuration of the VCSEL array 504, the thermally-conductive material used to bond the sides 523 of the VCSEL array 504 to the sidewalls of the upwardly-directed recess 552, may also be electrically-conductive.

Like the VCSEL array 404 of the illumination system 402 of FIG. 5, the VCSEL array 504 of the illumination system 502 of FIG. 6 is configured to emit light through a substrate of the VCSEL array 504 and the VCSEL array 504 is bonded to the ceramic sub-mount 510 such that a light emitting surface 520 of the substrate of the VCSEL array 504 is directed upwardly.

One or more electrically-conductive connections are provided in the form of one or more wire-bonds 540 between one or more electrically-conductive contacts 532 of the electrical driver 506 and one or more electrically-conductive contacts 522 the VCSEL array 504. As a consequence of bonding both the electrical driver 506 and the VCSEL array 504 in the adjacent upwardly-directed recesses 550, 552 defined in the same ceramic sub-mount 510, the length of the wire-bonds 540 may be reduced relative to the length of the wire-bonds of known illumination systems. Consequently, the inductance between the electrical driver 506 and the VCSEL array 504 is reduced. Reducing the inductance between the electrical driver 506 and the VCSEL array 504 may reduce the optical pulse widths that may be generated by each VCSEL of the VCSEL array 504 for a given driving voltage level, thereby increasing the range of a TSS LIDAR system which includes the illumination system 502 of FIG. 6. Conversely, reducing the inductance between the electrical driver 506 and the VCSEL array 504 may reduce a driving voltage level required for a given speed of modulation of the VCSEL array 504 and a given optical pulse width relative to known illumination systems. Reducing the driving voltage level required reduces the amount of heat generated or dissipated by the illumination system 502 relative to known illumination systems. Reducing the amount of heat generated or dissipated by the illumination system 502 also simplifies the cooling requirements relative to known illumination systems and improves the reliability of the illumination system 502 relative to known illumination systems.

Conversely, reducing the inductance between the electrical driver 506 and the VCSEL array 504 may allow more rapid modulation of the VCSEL array 504 for a given driving voltage level relative to known illumination systems.

In other respects, the structure and functionality of the illumination system 502 of FIG. 6 is similar to the structure and functionality of the illumination system 402 of FIG. 5.

Referring to FIG. 7, there is shown a sixth illumination system generally designated 602 for a LIDAR system. The illumination system 602 of FIG. 7 includes many features which correspond closely to the features of the illumination system 502 of FIG. 6, with features of the illumination system 602 of FIG. 7 being represented by the same reference numerals as the like features of the illumination system 502 of FIG. 6 incremented by “100”. Like the illumination system 502 of FIG. 6, the illumination system 602 of FIG. 7 includes a support member in the form of a ceramic sub-mount 610. The illumination system 602 also includes an optical emitter device in the form of a VCSEL array 604 mounted on the ceramic sub-mount 610, an electrical driver 606 mounted on the ceramic sub-mount 610, and one or more electrically conductive connections between the electrical driver 606 and the VCSEL array 604. The electrical driver 606 is configured to supply an electrical signal to the VCSEL array 604 via the one or more electrically conductive connections.

Like the ceramic sub-mount 510 of the illumination system 502 of FIG. 6, the ceramic sub-mount 610 defines a first upwardly-directed recess 650 in an upper surface 656 of the ceramic sub-mount 610 and a second upwardly-directed recess 652 in the upper surface 656 of the ceramic sub-mount 610. The ceramic sub-mount 610 further includes one or more electrical conductors 654 in the form of one or more electrically conductive tracks which extend along an outer surface of the ceramic sub-mount 610 and/or through the ceramic sub-mount 610.

The electrical driver 606 is located in first upwardly directed recess 650. A lower surface 631 of the electrical driver 606 is bonded to a bottom of the upwardly-directed recess 650 using a thermally- and electrically-conductive material (not shown) such as a thermally- and electrically-conductive adhesive, a thermally- and electrically-conductive glue, a thermally- and electrically-conductive epoxy, a thermally- and electrically-conductive solder, or the like so as to form an electrically conductive connection to one or more of the electrical conductors 654 of the ceramic sub-mount 610. The sides 633 of the electrical driver 606 may also be bonded to the sidewalls of the upwardly-directed recess 650 using a thermally-conductive material (not shown) such as a thermally-conductive adhesive, a thermally-conductive glue, a thermally-conductive epoxy, or the like to improve the conduction of heat from the sides 633 of the electrical driver 606 to the ceramic sub-mount 610. Depending on the configuration of the electrical driver 606, the thermally-conductive material used to bond the sides 633 of the electrical driver 606 to the sidewalls of the upwardly-directed recess 650, may also be electrically-conductive.

Similarly, the VCSEL array 604 is located in second upwardly-directed recess 652 in the upper surface 656 of the ceramic sub-mount 610. A lower surface 621 of the VCSEL array 604 is bonded to the bottom of the upwardly-directed recess 652 using a thermally- and electrically-conductive material (not shown) such as a thermally- and electrically-conductive adhesive, a thermally- and electrically-conductive glue, a thermally- and electrically-conductive epoxy, a thermally- and electrically-conductive solder, or the like so as to form an electrically conductive connection to one or more of the electrical conductors 654 of the ceramic sub-mount 610. The sides 623 of the VCSEL array 604 may also be bonded to the sidewalls of the upwardly-directed recess 652 using a thermally-conductive material (not shown) such as a thermally-conductive adhesive, a thermally-conductive glue, a thermally-conductive epoxy, or the like to improve the conduction of heat from the sides 623 of the VCSEL array 604 to the ceramic sub-mount 610. Depending on the configuration of the VCSEL array 604, the thermally-conductive material used to bond the sides 623 of the VCSEL array 604 to the sidewalls of the upwardly-directed recess 652, may also be electrically-conductive.

Like the VCSEL array 504 of the illumination system 502 of FIG. 6, the VCSEL array 604 of the illumination system 602 of FIG. 7 is configured to emit light through a substrate of the VCSEL array 604 and the VCSEL array 604 is bonded to the ceramic sub-mount 610 such that a light emitting surface 620 of the substrate of the VCSEL array 604 is directed upwardly.

One or more electrically-conductive connections are provided in the form of one or more wire-bonds 640 between one or more electrically-conductive contacts 632 of the electrical driver 606 and one or more electrically-conductive contacts 622 the VCSEL array 604. As a consequence of bonding both the electrical driver 606 and the VCSEL array 604 in the adjacent upwardly-directed recesses 650, 652 defined in the same ceramic sub-mount 610, the length of the wire-bonds 640 may be reduced relative to the length of the wire-bonds of known illumination systems. Consequently, the inductance between the electrical driver 606 and the VCSEL array 604 is reduced. Reducing the inductance between the electrical driver 606 and the VCSEL array 604 may reduce the optical pulse widths that may be generated by each VCSEL of the VCSEL array 604 for a given driving voltage level, thereby increasing the range of a TSS LIDAR system which includes the illumination system 602 of FIG. 7. Conversely, reducing the inductance between the electrical driver 606 and the VCSEL array 604 may reduce a driving voltage level required for a given speed of modulation of the VCSEL array 604 and a given optical pulse width relative to known illumination systems. Reducing the driving voltage level required reduces the amount of heat generated or dissipated by the illumination system 602 relative to known illumination systems. Reducing the amount of heat generated or dissipated by the illumination system 602 also simplifies the cooling requirements relative to known illumination systems and improves the reliability of the illumination system 602 relative to known illumination systems.

Conversely, reducing the inductance between the electrical driver 606 and the VCSEL array 604 may allow more rapid modulation of the VCSEL array 604 for a given driving voltage level relative to known illumination systems.

Moreover, the wire-bonds 640 are encapsulated in a protective material 680 such as an epoxy so as to form a “glob-top” for improved robustness of the wire-bonds 640 and improved reliability of the illumination system 602 relative to known illumination systems.

In other respects, the structure and functionality of the illumination system 602 of FIG. 7 is similar to the structure and functionality of the illumination system 502 of FIG. 6.

One of ordinary skill in the art will understand that various modifications may be made to the illumination system and methods described above without departing from the scope of the present disclosure. For example, rather than defining a safety circuit like safety circuit 154a which extends from the ceramic sub-mount 110 to the cover member 170 as shown in FIG. 2, the illumination system 102 may include an external safety circuit which is external to the ceramic sub-mount 110 and which extends from the electrical driver 106 to the cover member 170. In the event that the cover member 170 should become detached from the ceramic sub-mount 110, the external safety circuit is broken. This may result in a significant change in the resistance of the external safety circuit and/or in the electrical current flowing through the external safety circuit which is/are detected by the electrical driver 106. The electrical driver 106 detects the change in the resistance of the external safety circuit and/or the change in the electrical current flowing through the external safety circuit and interrupts, switches off or prevents the transmission of any electrical signals from the electrical driver 106 to the VCSEL array 104.

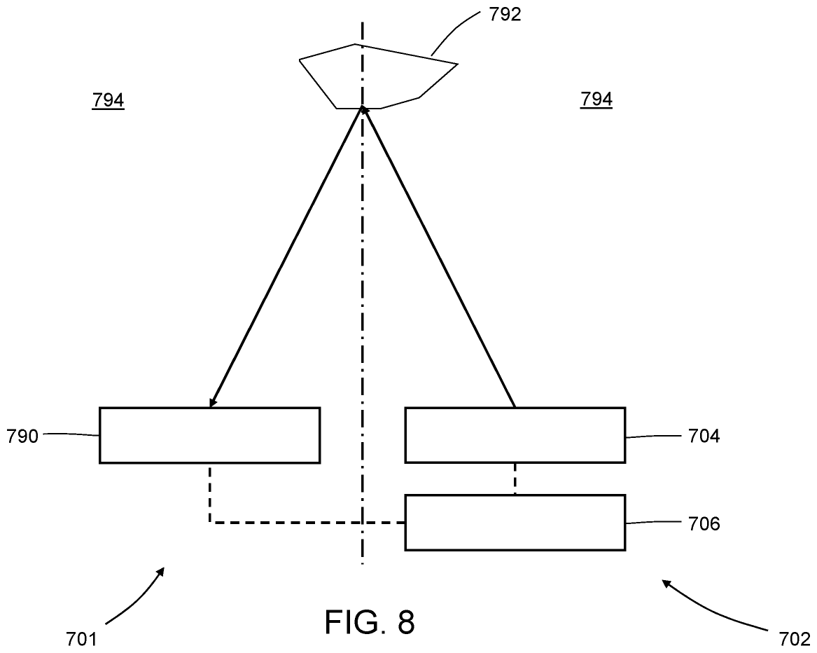

Embodiments of the present disclosure can be employed in many different applications including in sensing such as 3D sensing and LIDAR. For example, FIG. 8 shows a LIDAR system generally designated 701 comprising an illumination system generally designated 702 which includes an electrical driver 706 and an optical emitter device in the form of a VCSEL array 704. The LIDAR system 701 further includes an
optical receiver system generally designated 790. As indicated by the dashed lines in FIG. 8, the LIDAR system 701 includes one or more electrically-conductive connections between the electrical driver 706 and the VCSEL array 704. Similarly, the optical receiver system 790 is configured for communication with the electrical driver 706.

In use, the optical receiver system 790 generates an electrical signal which is representative of a power of an optical signal received by the optical receiver system 790 and the electrical driver 706 controls the electrical signal used to drive the VCSEL array 704 according to the electrical signal generated by the optical receiver system 790. For example, as shown in FIG. 8, the electrical signal generated by the optical receiver system 790 may comprise an optical signal which is emitted by the illumination system 702, transmitted to an object 792 in a scene 794 to be sensed, and directed, for example reflected or scattered, from the object 792 to the optical receiver system 790. The electrical driver 706 then controls the electrical signal used to drive the VCSEL array 704 according to the electrical signal generated by the optical receiver system 790 to control the optical power emitted by the VCSEL array 704 for automatic gain control of the LI DAR system 701.

Additionally or alternatively, the electrical signal generated by the optical receiver system 790 may be representative of ambient light in the scene 794 to be sensed and the electrical driver 706 may control the electrical signal used to drive the VCSEL array 704 according to the electrical signal generated by the optical receiver system 790 for dynamic control of the optical power emitted by the VCSEL array 704 based on the ambient light conditions in the scene 794.

Although preferred embodiments of the disclosure have been described in terms as set forth above, it should be understood that these embodiments are illustrative only and that the claims are not limited to those embodiments. Those skilled in the art will understand that various modifications may be made to the described embodiments without departing from the scope of the appended claims. Each feature disclosed or illustrated in the present specification may be incorporated in any embodiment, either alone, or in any appropriate combination with any other feature disclosed or illustrated herein. In particular, one of ordinary skill in the art will understand that one or more of the features of the embodiments of the present disclosure described above with reference to the drawings may produce effects or provide advantages when used in isolation from one or more of the other features of the embodiments of the present disclosure and that different combinations of the features are possible other than the specific combinations of the features of the embodiments of the present disclosure described above.

The skilled person will understand that in the preceding description and appended claims, positional terms such as ‘above’, ‘along’, ‘side’, etc. are made with reference to conceptual illustrations, such as those shown in the appended drawings. These terms are used for ease of reference but are not intended to be of limiting nature. These terms are therefore to be understood as referring to an object when in an orientation as shown in the accompanying drawings.

Use of the term “comprising” when used in relation to a feature of an embodiment of the present disclosure does not exclude other features or steps. Use of the term “a” or “an” when used in relation to a feature of an embodiment of the present disclosure does not exclude the possibility that the embodiment may include a plurality of such features.

The use of reference signs in the claims should not be construed as limiting the scope of the claims.

### LIST OF REFERENCE NUMERALS

2 prior art illumination system;
4 VCSEL array;
6 electrical driver;
10 ceramic sub-mount;
12 ceramic sub-mount;
14 PCB;
20 upper surface of the VCSEL array;
22 electrical contacts of the VCSEL array;
30 upper surface of the electrical driver;
32 electrical contacts of the electrical driver;
40 wire-bonds;
102 illumination system;
104 VCSEL array;
106 electrical driver;
110 ceramic sub-mount;
114 PCB;
120 upper surface of the VCSEL array;
121 lower surface of the VCSEL array;
122 electrical contacts of the VCSEL array;
130 upper surface of the electrical driver;
131 lower surface of the electrical driver;
132 electrical contacts of the electrical driver;
140 wire-bonds;
150 downwardly-disposed recess defined by ceramic sub-mount;
151 downwardly-disposed surface of downwardly-disposed recess;
152 upwardly-disposed recess defined by ceramic sub-mount;
153 upwardly-disposed surface of upwardly-disposed recess;
154 electrical conductors;
154a safety circuit;
160 filler material;
162 thermally-conductive material;
164 thermally-conductive material;
170 transparent cover member;
202 illumination system;
204 VCSEL array;
206 electrical driver;
210 ceramic sub-mount;
214 PCB;
220 upper surface of the VCSEL array;
221 lower surface of the VCSEL array;
222 electrical contacts of the VCSEL array;
230 upper surface of the electrical driver;
231 lower surface of the electrical driver;
232 electrical contacts of the electrical driver;
250 downwardly-disposed recess defined by ceramic sub-mount;
251 downwardly-disposed surface of downwardly-disposed recess;
252 upwardly-disposed recess defined by ceramic sub-mount;
253 upwardly-disposed surface of upwardly-disposed recess;
254 electrical conductors;
260 filler material;
261 filler material;
262 thermally-conductive material;
264 thermally-conductive material;
302 illumination system;
304 VCSEL array;
306 electrical driver;
310 ceramic sub-mount;
320 upper surface of the VCSEL array;
321 lower surface of the VCSEL array;
322 electrical contacts of the VCSEL array;
330 upper surface of the electrical driver;
331 lower surface of the electrical driver;
332 electrical contacts of the electrical driver;
354 electrical conductors;
356 upper surface of ceramic sub-mount;
402 illumination system;
404 VCSEL array;
406 electrical driver;
410 ceramic sub-mount;
420 upper surface of the VCSEL array;
421 lower surface of the VCSEL array;
422 electrical contacts of the VCSEL array;
430 upper surface of the electrical driver;
431 lower surface of the electrical driver;
432 electrical contacts of the electrical driver;
440 wire-bonds;
456 upper surface of ceramic sub-mount;
502 illumination system;
504 VCSEL array;
506 electrical driver;
510 ceramic sub-mount;
520 upper surface of the VCSEL array;
521 lower surface of the VCSEL array;
522 electrical contacts of the VCSEL array;
523 sides of the VCSEL array;
530 upper surface of the electrical driver;
531 lower surface of the electrical driver;
532 electrical contacts of the electrical driver;
533 sides of the electrical driver;
540 wire-bonds;
550 upwardly-directed recess;
552 upwardly-directed recess;
554 electrical conductors;
556 upper surface of ceramic sub-mount;
602 illumination system;
604 VCSEL array;
606 electrical driver;
610 ceramic sub-mount;
620 upper surface of the VCSEL array;
621 lower surface of the VCSEL array;
622 electrical contacts of the VCSEL array;
623 sides of the VCSEL array;
630 upper surface of the electrical driver;
631 lower surface of the electrical driver;
632 electrical contacts of the electrical driver;
633 sides of the electrical driver;
640 wire-bonds;
650 upwardly-directed recess;
652 upwardly-directed recess;
654 electrical conductors;
656 upper surface of ceramic sub-mount;
680 epoxy encapsulation;
701 LIDAR system;
702 illumination system;
704 VCSEL array;
706 electrical driver;
790 optical receiver system;
792 object; and
794 scene.

1. An illumination system comprising:
a support member;
an optical emitter device mounted on the support member;
an electrical driver mounted on the support member; and
one or more electrically conductive connections between the electrical driver and the optical emitter device,
wherein the electrical driver is configured to supply an electrical signal to the optical emitter device via the one or more electrically conductive connections, and wherein the support member comprises a thermally-conductive ceramic material, and wherein the electrical driver is mounted on a first side of the support member and the optical emitter device is mounted on a second side of the support member, wherein the second side of the support member is opposite to the first side of the support member.

2. The illumination system as claimed in claim 1, wherein at least one of:
the thermally-conductive ceramic material comprises, or is formed from, one or more of alumina (Al₂O₃), silicon nitride (Si₃N₄), silicon carbide (SiC), tungsten carbide (WC), a High Temperature Co-fired Ceramic (HTCC) material and a Low Temperature Co-fired Ceramic (LTCC) material;
the optical emitter device and/or the electrical driver have a thermally-conductive connection to the support member;
the illumination system comprises a thermally-conductive adhesive, glue, or filler material disposed between the support member and the optical emitter device for providing or enhancing a thermally-conductive connection between the support member and the optical emitter device;
the illumination system comprises a thermally-conductive adhesive, glue, or filler material disposed between the support member and the electrical driver for providing or enhancing a thermally-conductive connection between the support member and the electrical driver.

3. The illumination system as claimed in claim 1,
wherein at least one of:
the support member extends between the electrical driver and the optical emitter device;
the support member defines a space or a recess on the first side of the support member for accommodating the electrical driver;
the support member defines a space or a recess on the second side of the support member for accommodating the optical emitter device;
the electrical driver and the optical emitter device at least partially overlap when viewed in a direction normal to a light emitting surface of the optical emitter device;
the electrical driver and the optical emitter device are arranged in a stacked configuration; and
the electrical driver and the optical emitter device are vertically integrated.

4. The illumination system as claimed in claim 1,
wherein at least one of:
the optical emitter device and the electrical driver are mounted on the same side of the support member;
the support member defines a space or a recess on one side of the support member for accommodating both the optical emitter device and the electrical driver; the support member defines a first space or a first recess on one side of the support member for accommodating the electrical driver, and the support member defines a second space or a second recess on the same side of the support member for accommodating the optical emitter device.

5. The illumination system as claimed in claim 1, wherein at least one of:
the support member comprises one or more electrical conductors such as one or more electrically-conductive tracks and/or one or more electrically-conductive pads; one or more of the electrical conductors of the support member are defined on an outer surface of the support member;
one or more of the electrical conductors of the support member extends through the support member;
the support member defines one or more apertures, one or more through-holes, one or more vias or one or more channels, and wherein each of one or more of the electrical conductors of the support member extends through a corresponding aperture, a corresponding through-hole, a corresponding via, or a corresponding channel.

6. The illumination system as claimed in claim 5, wherein the electrical driver comprises one or more electrically-conductive contacts, and one or more of the electrical conductors of the support member has an electrically-conductive connection to one or more of the electrically-conductive contacts of the electrical driver.

7. The illumination system as claimed in claim 6, wherein at least one of:
the electrical driver is flip-chip bonded to the support member such that one or more of the electrically-conductive contacts of the electrical driver has an electrically-conductive connection to a corresponding electrical conductor of the support member;
the illumination system comprises an electrically-insulating adhesive, glue, or filler material located between the electrical driver and the support member.

8. The illumination system as claimed in claim 6, wherein at least one of:
the illumination system comprises one or more wire-bonds, wherein each wirebond provides an electrically-conductive connection between an electrically-conductive contact of the electrical driver and a corresponding electrical conductor of the support member;
each of one or more of the wire-bonds is encapsulated by a protective material.

9. The illumination system as claimed in claim 5, wherein the optical emitter device comprises one or more electrically-conductive contacts, and wherein one or more of the electrical conductors of the support member has an electrically-conductive connection to one or more of the electrically-conductive contacts of the optical emitter device.

10. The illumination system as claimed in claim 9, wherein at least one of:
the optical emitter device is flip-chip bonded to the support member such that one or more of the electrically-conductive contacts of the optical emitter device has an electrically-conductive connection to a corresponding electrical conductor of the support member;
the illumination system comprises an electrically-insulating adhesive, glue, or filler material located between the optical emitter device and the support member.

11. The illumination system as claimed in claim 9, further comprising one or more wirebonds, wherein each wire-bond provides an electrically-conductive connection between an electrically-conductive contact of the optical emitter device and a corresponding electrical conductor of the support member;
each of one or more of the wire-bonds is encapsulated by a protective material.

12. The illumination system as claimed in claim 5, further comprising an electrical interconnection member, wherein at least one of:
the electrical interconnection member defines one or more electrical conductors; the electrical interconnection member comprises a circuit board;
the support member is mounted on the electrical interconnection member; the support member has a thermally-conductive connection to the electrical interconnection member;
a first side of the support member is attached to the electrical interconnection member;
the electrical driver has a thermally-conductive connection to the electrical interconnection member;
the illumination system comprises a thermally-conductive material disposed between the electrical driver and the electrical interconnection member for providing or enhancing a thermally-conductive connection between the electrical driver and the electrical interconnection member;
the thermally-conductive material disposed between the electrical driver and the electrical interconnection member comprises any combination of one or more of thermally-conductive adhesive, glue, and filler material;
the electrical driver has an electrically-conductive connection to the electrical interconnection member;
the illumination system comprises an electrically-conductive material disposed between the electrical driver and the electrical interconnection member for providing or enhancing an electrically-conductive connection between the electrical driver and the electrical interconnection member;
the electrically-conductive material disposed between the electrical driver and the electrical interconnection member comprises any combination of one or more of electrically-conductive adhesive, glue, filler material, and solder.

13. The illumination system as claimed in claim 12, wherein at least one of:
each of one or more of the electrical conductors of the support member provides an electrically-conductive connection between the electrical driver and a corresponding electrical conductor of the electrical interconnection member;
each of one or more of the electrical conductors of the support member provides an electrically-conductive connection between the optical emitter device and a corresponding electrical conductor of the electrical interconnection member.

14. The illumination system as claimed in claim 12, wherein the electrical driver is disposed between the electrical interconnection member and the optical emitter device.

15. The illumination system as claimed in claim 1, further comprising a transparent cover member, and wherein at least one of:
the cover member is attached to the support member;
the cover member is transparent to light emitted by the optical emitter device; the cover member comprises an anti-reflection (AR) coating for minimizing a reflectivity of the cover member with respect to the light emitted by the optical emitter device.

16. The illumination system as claimed in claim 15, further comprising a safety circuit that extends from the electrical driver to the cover member along, or through, the support member, wherein the electrical driver may be configured to interrupt or switch off the electrical signal used to drive the optical emitter device based on a resistance of the safety circuit and/or an electrical current flowing through the safety circuit.

17. The illumination system as claimed in claim 1, wherein at least one of:
the optical emitter device comprises a surface-emitting optical emitter device;
the optical emitter device comprises a VCSEL;
the optical emitter device is configured to emit visible and/or infra-red light; the optical emitter device comprises one or more light emitting layers and a substrate, wherein the one or more light emitting layers are disposed on the substrate;
the optical emitter device is configured to emit light through a light emitting surface is on an opposite side of the one or more light emitting layers to the substrate;
the optical emitter device is a top-emitting optical emitter device;
the optical emitter device is configured to emit light through a light emitting surface is on the same side of the one or more light emitting layers as the substrate;
the optical emitter device is a bottom-emitting optical emitter device configured to emit light through the substrate.

18. The illumination system as claimed in claim 1, further comprising a plurality of optical emitter devices, wherein at least one of:
the plurality of optical emitter devices comprises an array of optical emitter devices;
the array of optical emitter devices comprises a 2D array of optical emitter devices;
the array of optical emitter devices comprises a non-addressable array of optical emitter devices;
the array of optical emitter devices comprises an addressable array of optical emitter devices;
one or more of the optical emitter devices comprises a surface-emitting optical emitter device;
one or more of the optical emitter devices comprises a VCSEL;
the array of optical emitter devices comprises a VCSEL array;
one or more of the optical emitter devices is configured to emit visible and/or infra-red light;
one or more of the optical emitter devices comprises one or more light emitting layers and a substrate, wherein the one or more light emitting layers are disposed on the substrate;
one or more of the optical emitter devices is configured to emit light through a light emitting surface on an opposite side of the one or more light emitting layers to the substrate;
one or more of the optical emitter devices is a top-emitting optical emitter device;
one or more of the optical emitter devices is configured to emit light through the substrate;
one or more of the optical emitter devices is a bottom-emitting optical emitter device.

19. A sensing system, the sensing system comprising the illumination system as claimed in claim 1.

20. The sensing system as claimed in claim 19, further comprising an optical receiver system, wherein the optical receiver system is configured to generate an electrical signal representative of a power of an optical signal received by the optical receiver system and wherein the electrical driver is configured to control the electrical signal used to drive the optical emitter device according to the electrical signal generated by the optical receiver system and, optionally, wherein at least one of:
the optical signal received by the optical receiver system comprises an optical signal emitted by the illumination system, transmitted from the illumination system to an object in a scene to be sensed and directed from the object to the optical receiver system;
the optical signal received by the optical receiver system is representative of ambient light in a scene to be sensed.
